(19) United States
(12) Patent Application Publication
(10) Pub. No.: US 2011/0175856 A1
(43) Pub. Date: Jul. 21, 2011

(54) ELECTROPHORETIC DISPLAY PANEL, METHOD OF MANUFACTURING THE SAME AND DISPLAY APPARATUS HAVING THE SAME

(76) Inventors: Wang-Su Hong, Gyeonggi-do (KR); Seung-Jin Baek, Seoul (KR); Jang-Kyum Kim, Seoul (KR)

(21) Appl. No.: 12/849,772

(22) Filed: Aug. 3, 2010

(30) Foreign Application Priority Data
Jan. 15, 2010 (KR) 2010-0003974

(51) Int. Cl. G09G 5/00; G09G 3/34; H01L 33/00

(52) U.S. Cl. 345/204; 345/107; 438/26; 257/E33.053; 257/E33.056

(57) ABSTRACT

An electrophoretic display panel includes a first member, a second member, an electrophoretic layer and an outer member. The first member includes a first substrate and a pixel electrode formed on the first substrate. The first substrate has a display area and a dummy area disposed outside of the display area. The second member includes a second substrate facing the first substrate and a common electrode formed on a first surface of the second substrate. The electrophoretic layer is disposed between the first member and the second member and displays an image by an electric field generated between the pixel electrode and the common electrode. The outer member covers the dummy area and blocks light, so that display quality is improved.

### PRIORITY STATEMENT

This application claims priority under 35 U.S.C. §119 to Korean Patent Application No. 2010-0003974, filed on Jan. 15, 2010 in the Korean Intellectual Property Office (KIPO), the contents of which are herein incorporated by reference in their entirety.

### BACKGROUND OF THE INVENTION

1. Field of the Invention

The present invention relates generally to an electrophoretic display panel, a method of manufacturing the electrophoretic display panel and an electrophoretic display apparatus having the electrophoretic display panel. More particularly, the present invention relates to an electrophoretic display panel having improved image quality, a method of manufacturing the electrophoretic display panel and an electrophoretic display apparatus having the electrophoretic display panel.

2. Description of the Related Art

An electrophoretic display apparatus is a type of display that offers high reflectivity, high contrast ratio, and consistent image quality that is not dependent on viewing angle. In addition, an electrophoretic display apparatus has other advantages over commonly-used display apparatuses such as liquid crystal displays (LCDs) because it does not require a polarizing film, an alignment film and a liquid crystal layer. Hence, compared to a liquid crystal display apparatus, thus the electrophoretic display apparatus may be manufactured at a lower cost.

The electrophoretic display apparatus includes two substrate members and an electrophoretic layer formed between them.

When the substrate members are combined, the first substrate member and the second substrate member are combined in the display area and in an area outside of a display area.

With this configuration, sometimes, an electric field is generated between the second member and the first member in the area outside of the display area, causing a black visual artifact, white visual artifact, or a stain pattern mixed with black and white to be displayed in the area outside of the display area due to the electric field.

The presence of these black, white, and stain patterns displayed in the area outside of the display area undesirably decreases image quality.

### SUMMARY OF THE INVENTION

The present invention provides an electrophoretic display panel having improved image quality.

The present invention also provides a method of manufacturing the above-mentioned electrophoretic display panel.

The present invention also provides an electrophoretic display apparatus having the above-mentioned electrophoretic display panel.

In one aspect of the present invention, an electrophoretic display panel includes a first member, a second member, an electrophoretic layer and an outer member. The first member includes a first substrate and a pixel electrode formed on the first substrate. The first substrate has a display area and a dummy area disposed outside of the display area. The second member includes a second substrate facing the first substrate and a common electrode formed on a first surface of the second substrate. The electrophoretic layer is disposed between the first member and the second member and displays an image by an electric field generated between the pixel electrode and the common electrode. The outer member covers the dummy area and blocks light.

The electrophoretic display panel may further include a protective film formed on the second substrate and covering the display area, and the outer member and the protective film may be formed on substantially the same plane.

The outer member may be formed on the first surface of the second substrate, and the common electrode may cover the outer member.

The outer member may be formed on the common electrode.

The outer member may be achromatic, and may be black.

The electrophoretic display panel may further include a protective film formed on a second surface of the second substrate and covering the display area. The outer member may be formed on the protective film and cover the dummy area.

The first substrate may further include at least one thin-film transistor (TFT) formed in a driving area adjacent to the dummy area and applying a gate signal to a gate line of the display area.

The outer member may overlap with the driving area in which the TFT is formed.

The width of the outer member corresponding to upper and lower side portions of the dummy area may be uniform.

The width of the outer member corresponding to left and right side portions of the dummy area may be uniform.

The width of the outer member corresponding to upper, lower, left and right side portions of the dummy area may be uniform.

In another aspect of the present invention, there is provided a method of manufacturing an electrophoretic display panel. In the method, a first member including a first substrate and a pixel electrode formed on the first substrate is formed. A second member including a second substrate facing the first substrate and a common electrode formed on a first surface of the second substrate is formed. An electrophoretic layer is formed on either the first or the second member. The first member and the second member are combined to sandwich the electrophoretic layer between them. An outer member is formed on the second member. The first substrate has a display area and a dummy area disposed outside of the display area, and the outer member covers the dummy area and blocks light.

The outer member may be formed via a coating process.

The outer member may be formed via a film lamination process.

In one embodiment, the first member may further include a driving area adjacent to the dummy area, and the outer member may be formed in an area overlapping with the driving area.

In yet another aspect of the present invention, an electrophoretic display apparatus includes a first member, a second member, an electrophoretic layer, an outer member, a gate driving part and a data driving part. The first member includes a first substrate and a pixel electrode formed on the first substrate. The first substrate has a display area and a dummy area disposed outside of the display area. The second member includes a second substrate facing the first substrate and a common electrode formed on a first surface of the second substrate. The electrophoretic layer is disposed between the first member and the second member and displays an image by an electric field generated between the pixel electrode and the common electrode. The outer member covers the dummy area and blocks light. The gate driving part applies a gate signal to a gate line of the display area. The data driving part applies a data signal to a data line of the display area.

The gate driving part may be disposed in a driving area adjacent to the dummy area, and include at least one TFT applying the gate signal to the gate line of the display area.

The outer member may overlap with the driving area.

According to the present invention, an outer member covers a dummy area disposed outside of a display area, preventing a display of a random color in the dummy area. Therefore, image quality of the electrophoretic display apparatus may be enhanced.

### BRIEF DESCRIPTION OF THE DRAWINGS

The above and other features and advantages of the present invention will become more apparent through description of embodiments with reference to the accompanying drawings, in which:

FIG. 1 is a conceptual diagram illustrating an electrophoretic display apparatus according to an embodiment of the present invention;

FIG. 2 is a cross-sectional view taken along a line I-I′ in FIG. 1 to illustrate a dummy area and a portion of the display area of the electrophoretic display panel of FIG. 1;

FIGS. 3A, 3B, 3C, 3D, 3E, 3F, 3G and 3H are cross-sectional views illustrating a method of manufacturing the electrophoretic display panel of FIG. 2;

FIG. 4 is a cross-sectional view illustrating a dummy area and a portion of a display area of an electrophoretic display panel according to another embodiment of the present invention;

FIGS. 5A, 5B, 5C, 5D, 5E and 5F are cross-sectional views illustrating a method of manufacturing the electrophoretic display panel of FIG. 4;

FIG. 6 is a cross-sectional view illustrating a dummy area and a portion of a display area of an electrophoretic display panel according to still another embodiment of the present invention;

FIGS. 7A, 7B, 7C, 7D, 7E and 7F are cross-sectional views illustrating a method of manufacturing the electrophoretic display panel of FIG. 6;

FIG. 8 is a cross-sectional view illustrating a dummy area and a portion of a display area of an electrophoretic display panel according to still another embodiment of the present invention;

FIGS. 9A, 9B, 9C, 9D, 9E and 9F are cross-sectional views illustrating a method of manufacturing the electrophoretic display panel of FIG. 8;

FIG. 10 is a cross-sectional view illustrating a dummy area and a portion of a display area of an electrophoretic display panel according to still another embodiment of the present invention;

FIGS. 11A, 11B and 11C are cross-sectional views illustrating a method of manufacturing the electrophoretic display panel of FIG. 10;

FIG. 12A is a conceptual diagram illustrating an electrophoretic display apparatus according to still another embodiment of the present invention;

FIG. 12B is an enlarged view illustrating a portion ‘A’ of FIG. 12A;

FIG. 13 is a cross-sectional view taken along a line II-II′ in FIG. 12A to illustrate a driving area, a dummy area and a portion of a display area of an electrophoretic display panel in FIG. 12A; and

FIGS. 14A, 14B, 14C, 14D, 14E, 14F, 14G, 14H and 14I are cross-sectional views illustrating a method of manufacturing the electrophoretic display panel of FIG. 13.

### DETAILED DESCRIPTION

The present invention is described more fully hereinafter with reference to the accompanying drawings, in which embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings. The invention reduces or prevents undesirable visual artifacts from forming in the area outside of the display area in an electrophoretic display device by strategically placing a light-blocking member in the area around the display area.

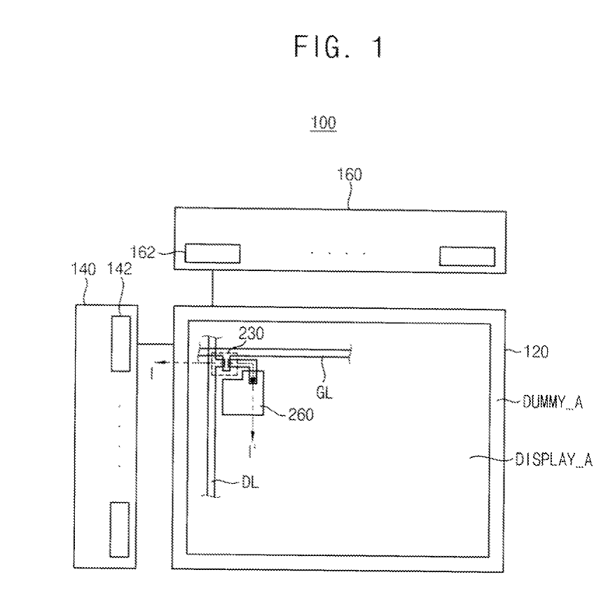

FIG. 1 is a conceptual diagram illustrating an electrophoretic display apparatus according to an embodiment of the present invention.

Referring to FIG. 1, the electrophoretic display apparatus 100 according to the present embodiment includes an electrophoretic display panel 120, a gate driving part 140 and a data driving part 160.

The electrophoretic display panel 120 includes a display area DISPLAY_A in which a gate line GL and a data line DL intersecting with the gate line GL are formed and a dummy area DUMMY_A formed outside of the display area DISPLAY_A.

The gate driving part 140 includes a plurality of gate driving chips 142. The gate driving chip 142 applies a gate signal to the gate line GL of the electrophoretic display panel 120 to activate a thin-film transistor (TFT) 230 connected to the gate line GL.

The data driving part 160 includes a plurality of data driving chips 162. The data driving chip 162 applies a data signal to the TFT 230 through the data line DL of the electrophoretic display panel 120.

For example, the gate driving part 140 may be formed on the electrophoretic display panel 120. Alternatively, the data driving part 160 may be formed on the electrophoretic display panel 120. In addition, the gate driving part 140 and the data driving part 160 may be formed on the electrophoretic display panel 120.

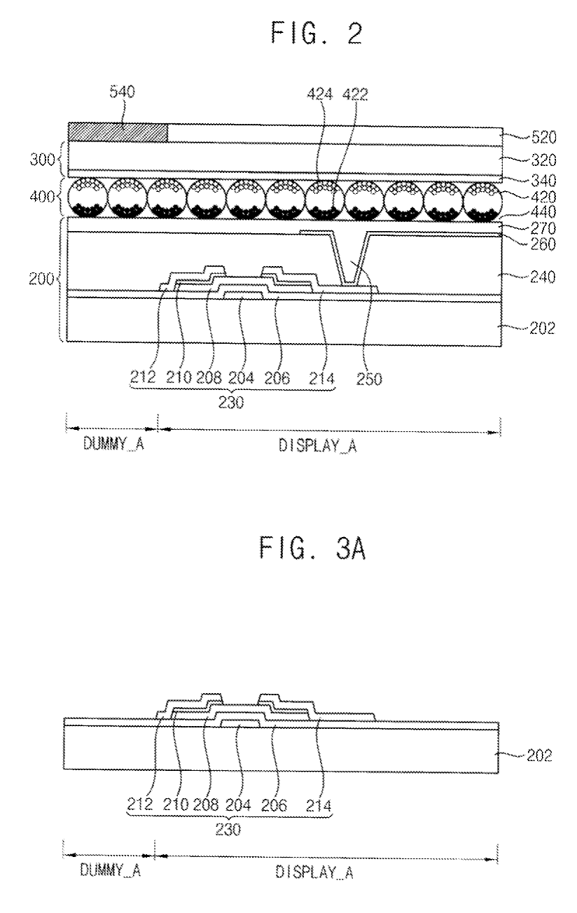

FIG. 2 is a cross-sectional view taken along a line I-I′ in FIG. 1 to illustrate a dummy area and a portion of the display area of the electrophoretic display panel of FIG. 1.

Referring to FIG. 2, the electrophoretic display panel 120 includes a first member 200, a second member 300, an electrophoretic layer 400, a protective film 520 and an outer member 540.

The first member 200 includes a first substrate 202 having the display area DISPLAY_A and the dummy area DUMMY_A, the TFT 230 formed on the first substrate 202, a protection film 240 formed on the TFT 230, and a pixel electrode 260 formed on the protection film 240 and electrically connected to a drain electrode 214 of the TFT 230 through a contact hole 250 formed through the protection film 240.

The TFT 230 includes a gate electrode 204 formed on the first substrate 202 and extending from the gate line GL, a gate insulation layer 206 formed on the gate electrode 204, an active layer 208 formed on the gate insulation layer 206, an ohmic-contact layer 210 formed on the active layer 208, a source electrode 212 formed on the ohmic-contact layer 210 and extending from the data line DL, and the drain electrode 214 formed on the ohmic-contact layer 210 and spaced apart from the source electrode 212.

The first member 200 may further include an adhesive layer 270 on the protection film 240 and the pixel electrode 260, so that the protection film 240 and the pixel electrode 260 attach to the electrophoretic layer 400.

The second member 300 includes a second substrate 320 facing the first substrate 202 of the first member 200 and a common electrode 340 formed on a first surface of the second substrate 320. In the present embodiment, the first surface of the second substrate 320 is the rear surface of the second substrate 320, which is the surface closest to the electrophoretic layer 400.

The electrophoretic layer 400 is formed between the first member 200 and the second member 300.

The electrophoretic layer 400 displays an image using an electric field generated between the pixel electrode 260 of the first member 200 and the common electrode 340 of the second member 300.

The electrophoretic layer 400 includes a microcapsule 420 and a binder 440 protecting and fixing the microcapsule 420. The microcapsule 420 includes a black particle 422 charged with a negative (−) charge and a white particle 424 charged with a positive (+) charge.

Therefore, the black particle 422 responds to a positive voltage and the white particle 424 responds to a negative voltage. The black particle 422 may include a carbon material, and the white particle 424 may include a titanium dioxide (TiO2) material

When there is no electric field between the pixel electrode 260 of the first member 200 and the common electrode 340 of the second member 300, the black particle 422 and the white particle 424 are irregularly disposed in the microcapsule 420.

When the data voltage applied to the pixel electrode 260 is higher than a common voltage applied to the common electrode 340, the negatively-charged black particle 422 drifts toward the pixel electrode 260 and the positively-charged white particle 424 drifts toward the common electrode 340. In this case, the data voltage may be a positive voltage.

Therefore, when a positive electric field is generated between the pixel electrode 260 and the common electrode 340, light passing through the common electrode 340 is reflected by the white particle 424, causing the electrophoretic display panel 120 to display an image having a white grayscale.

When the second member 300 includes a color filter, the electrophoretic display panel 120 may display color corresponding to the color filter using the light reflected by the white particle 424.

When the data voltage applied to the pixel electrode 260 is lower than the common voltage applied to the common electrode 340, the positively-charged white particle 424 drifts toward the pixel electrode 260 and the negatively-charged black particle 422 drifts toward the common electrode 340. In this case, the data voltage may be a negative voltage.

Therefore, when a negative electric field is generated between the pixel electrode 260 and the common electrode 340, the light passing through the common electrode 340 is absorbed by the black particle 422, causing the electrophoretic display panel 120 to display an image having a black grayscale.

The protective film 520 and the outer member 540 are formed on the second member 300. The protective film 520 may be formed in an area covering the display area DISPLAY_A, and formed on a second surface opposite the first surface on which the common electrode 340 is formed. The outer member 540 is formed in an area covering the dummy area DUMMY_A, and formed on the second surface. With reference to FIG. 2, the second surface of the second substrate 320 is the upper surface of the second substrate 320.

The protective film 520 may transmit light. The protective film 520 may prevent moisture and ultraviolet ray from permeating into the electrophoretic layer 400 from outside of the electrophoretic display panel 120. For example, the protective film 520 may be formed by forming one of SiNₓ, SiO₂, SiOₓN_{y}, etc. on a plastic film.

The outer member 540 may extend from the protective film 520 formed in the area overlapping with the display area DISPLAY_A to overlap with the dummy area DUMMY_A. In the particular embodiment, the outer member 540 may be formed on a plane coplanar with a plane on which the protective film 520 is formed.

The outer member 540 may be achromatic. For example, the outer member 540 may have a black color. “Achromatic,” as used herein, is intended to mean black, white, or a gray mixture of the two.

In plan view, the width of the outer member 540 may be uniform outside of the display area DISPLAY_A. For example, the width of the outer member 540 corresponding to upper and lower sides of the dummy area DUMMY_A may be uniform. Alternatively, the width of the outer member 540 corresponding to left and right sides of the dummy area DUMMY_A may be uniform. In some embodiments, a width of the outer member 540 corresponding to the upper, lower, left and right sides of the dummy area DUMMY_A may be uniform.

The outer member 540 may include a material that absorbs light. For example, the outer member 540 may include an organic material such as carbon black. Thus, the outer member 540 may block light reflected by the electrophoretic layer 400.

As disclosed, the electrophoretic display apparatus 100 includes the outer member 540 covering the dummy area DUMMY_A disposed outside of the display area DISPLAY_A to prevent a random color from being displayed in the dummy area DUMMY_A. By preventing the formation of visual artifact in the dummy area DUMMY_A, the outer member 540 enhances image quality.

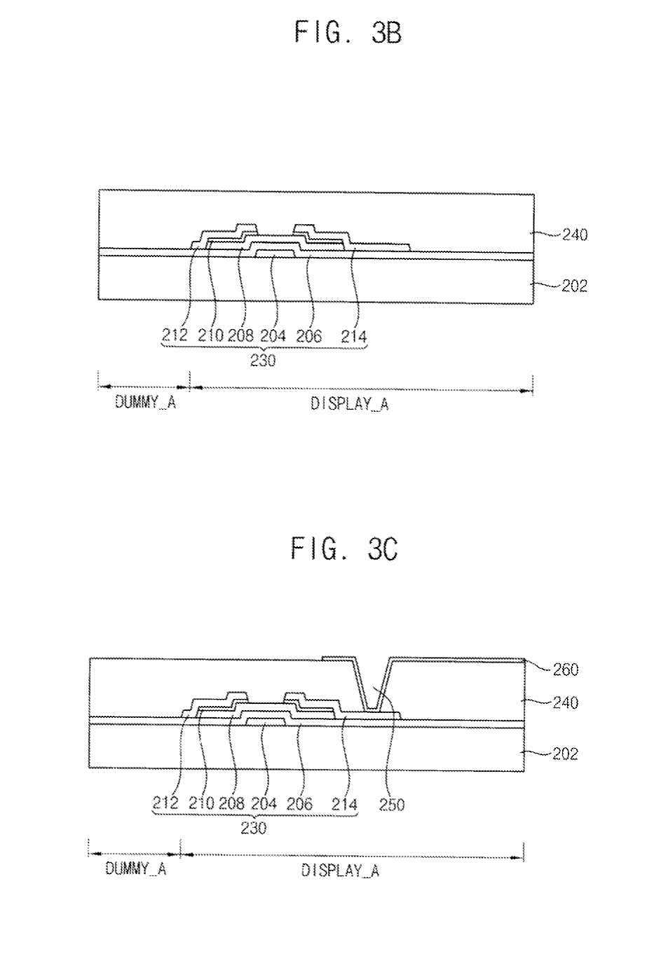

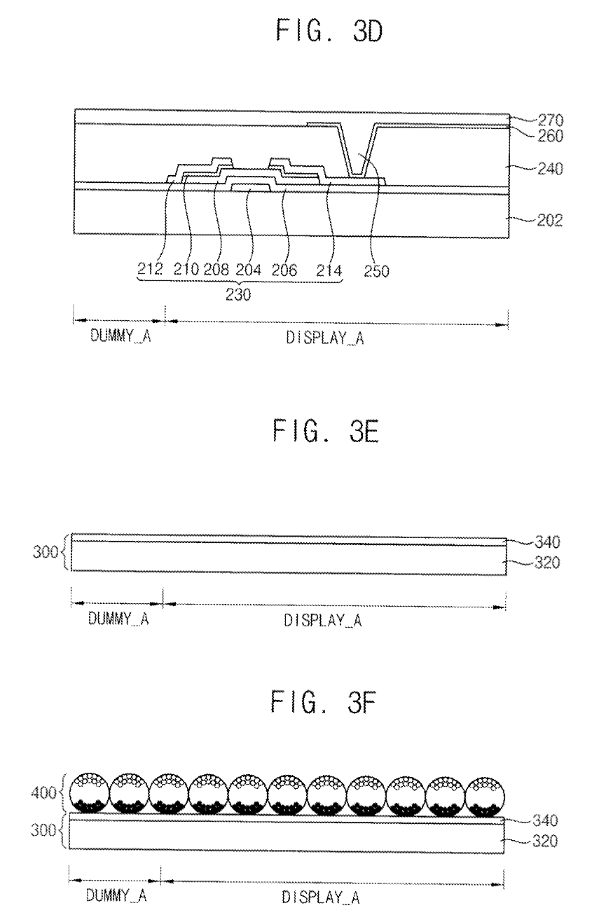

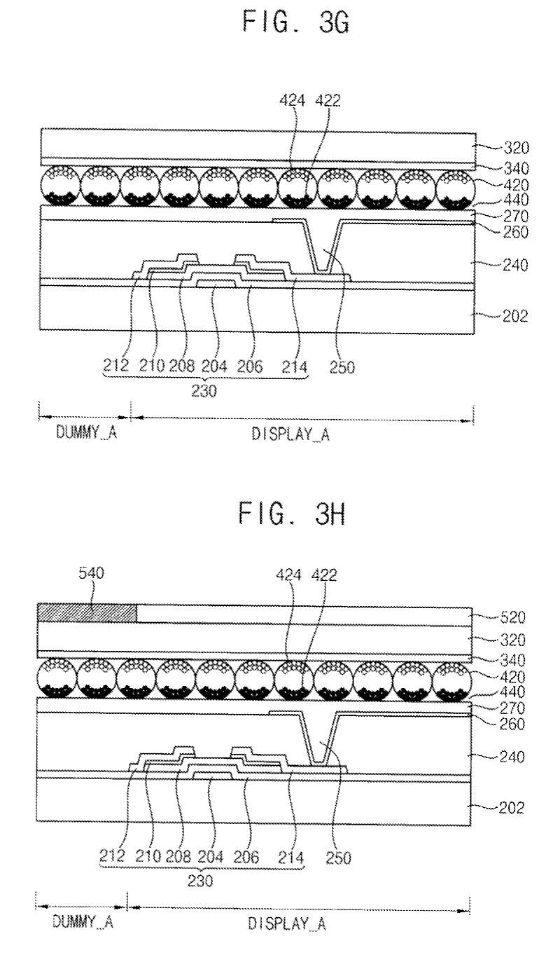

FIGS. 3A, 3B, 3C, 3D, 3E, 3F, 3G and 3H are cross-sectional views explaining a method of manufacturing the electrophoretic display panel of FIG. 2.

Referring to FIG. 3A, the TFT 230 is formed on the first substrate 202. For example, the gate electrode 204 extending from the gate line GL is formed on the first substrate 202. The gate insulation layer 206 is formed on the gate electrode 204. The active layer 208 is formed on the gate insulation layer 206. The ohmic-contact layer 210 is formed on the active layer 208 and separated into portions that are spaced apart from each other. The source electrode 212 extending from the data line DL and the drain electrode 214 spaced apart from the source electrode 212 are formed on the ohmic-contact layer 210.

Referring to FIG. 3B, the protection film 240 is formed on the first substrate 202 on which the TFT 230 is formed. The protection film 240 is formed to cover the TFT 230. The protection film 240 may include an organic material such as acrylic, polyimide, benzocyclobutene and so on.

Referring to FIG. 3C, the pixel electrode 260 is partially formed on the protection film 240. The pixel electrode 260 is electrically connected to the drain electrode 214 of the TFT 230 through the contact hole 250 formed through the protection film 240. The pixel electrode 260 may include indium tin oxide (ITO) or indium zinc oxide (IZO).

Referring to FIG. 3D, the adhesive layer 270 is formed on the pixel electrode 260 and the protection film 240. The adhesive layer 270 may include at least one of polyester resin, acrylic resin, epoxy resin and urethane resin.

Referring to FIG. 3E, the common electrode 340 is formed on the second substrate 320 to form the second member 300.

Referring to FIG. 3F, the electrophoretic layer 400 is formed on the common electrode 340 of the second member 300. The processes used for forming the above-described layers are well-known.

The electrophoretic layer 400 includes the microcapsule 420 and the binder 440 protecting and fixing the microcapsule 420. As described above, the microcapsule 420 includes negatively-charged black particle 422 and positively-charged white particle 424.

Referring to FIG. 3G, the first member 200 and the second member 300 on which the electrophoretic layer 400 is formed are combined with each other.

Referring to FIG. 3H, the protective film 520 and the outer member 540 are formed on the second member 300. For example, the protective film 520 is formed in the area covering the display area DISPLAY_A, and the outer member 540 is formed in the area covering the dummy area DUMMY_A.

The outer member 540 may be formed via a coating process or a film lamination process, which are well known.

The protective film 520 and the outer member 540 may be formed on the second member 300, after the protective film 520 formed in the area covering the display area DISPLAY_A and the outer member 540 formed in the area covering the dummy area DUMMY_A are combined with each other. After the protective film 520 is laminated on the second member 300, the outer member 540 may be formed by printing the outer member 540 outside of the protective film 520. For example, in printing the outer member 540 may be used a roll printing method such as a gravure printing, an offset printing and so on.

In addition, the outer member 540 may contact the protective film 520 and may be formed in the area covering the dummy area DUMMY_A after the protective film 520 is formed in the area covering the display area DISPLAY_A.

According to the embodiment described with reference to FIGS. 3A, 3B, 3C, 3D, 3E, 3F, 3G and 3H, the second member 300 is combined with the first member 200 after the electrophoretic layer 400 is formed on the second member 300. Alternatively, the first member 200 may be combined with the second member 300 after the electrophoretic layer 400 is formed on the first member 200.

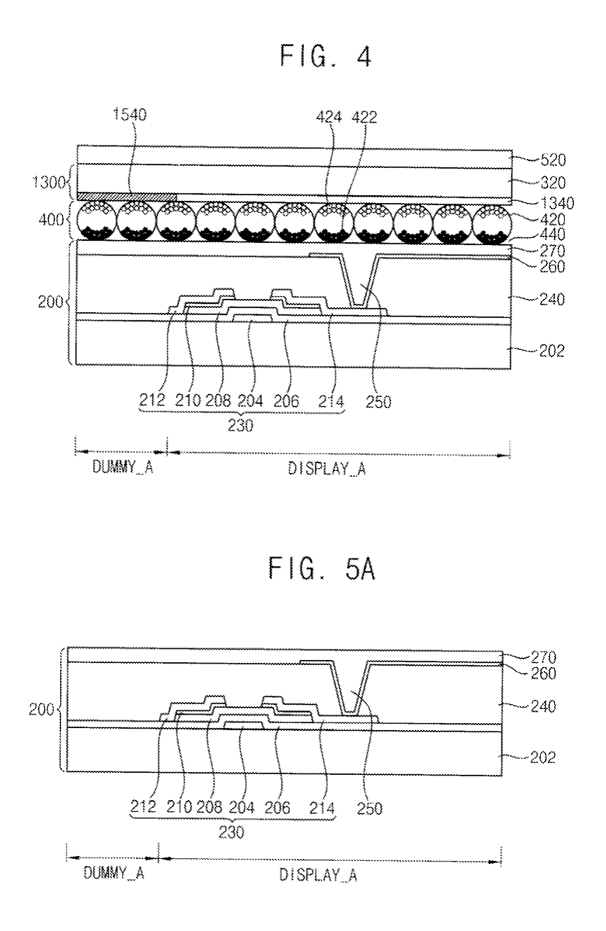

FIG. 4 is a cross-sectional view illustrating a dummy area and a portion of a display area of an electrophoretic display panel according to another embodiment of the present invention.

The electrophoretic display panel according to the present embodiment is substantially the same as the electrophoretic display panel according to the previous embodiment in FIG. 2 with one of the differences being the position of an outer member 1540. Thus, the same reference numerals will be used to refer to the parts described above and any repetitive explanation concerning those elements will be omitted.

Referring to FIG. 4 the electrophoretic display panel according to the present embodiment includes the first member 200, the second member 1300, the electrophoretic layer 400 and the protective film 520.

The second member 1300 includes the second substrate 320, a common electrode 1340 and the outer member 1540.

The common electrode 1340 may be formed on the second substrate 320 and in an area covering the display area DISPLAY_A.

The outer member 1540 may extend from the common electrode 1340 to cover the dummy area DUMMY_A disposed outside of the display area DISPLAY_A. For example, the outer member 1540 and the common electrode may be formed on substantially the same plane.

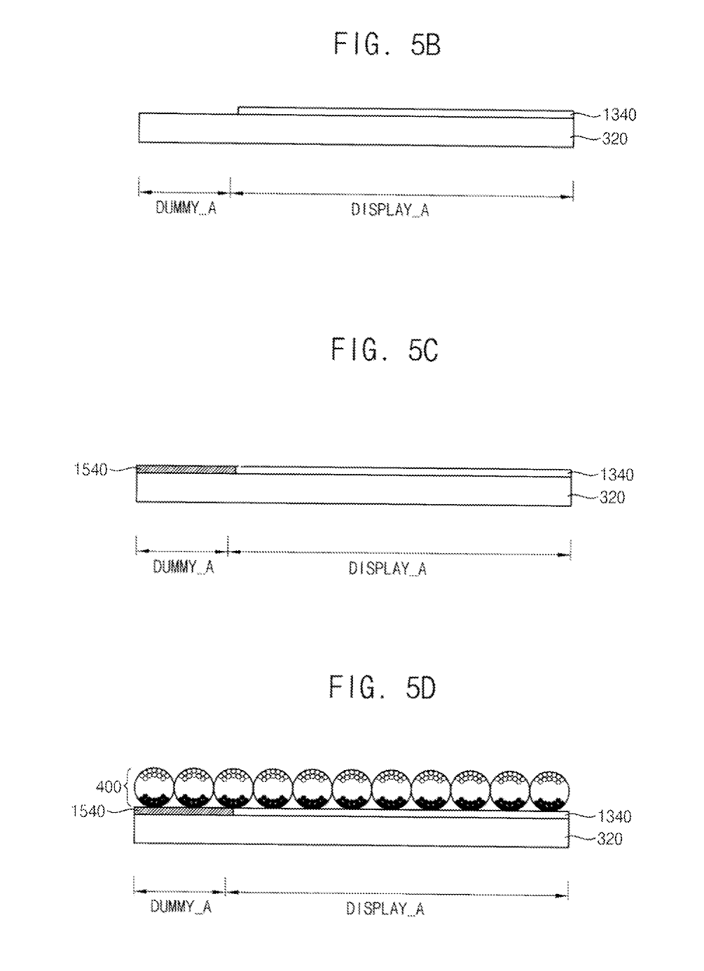

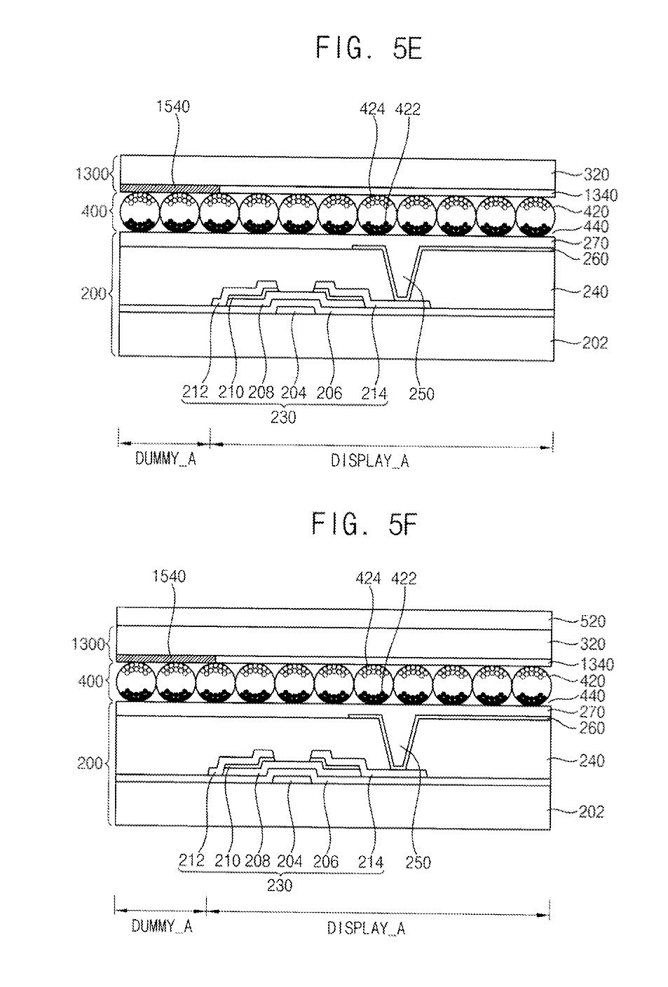

FIGS. 5A, 5B, 5C, 5D, 5E and 5F are cross-sectional views explaining a method of manufacturing the electrophoretic display panel of FIG. 4.

Referring to FIG. 5A, the first member 200 is formed. Forming the first member 200 may be done substantially in the manner described above with reference to FIGS. 3A, 3B, 3C and 3D.

Referring to FIG. 5B, the common electrode 1340 is formed on the second substrate 320 to overlap with the display area DISPLAY_A.

Referring to FIG. 5C, the outer member 1540 is formed on the second substrate 320 to overlap with the dummy area DUMMY_A.

Referring to FIG. 5D, the electrophoretic layer 400 is formed on the second member 1300 manufactured as illustrated in FIGS. 5B and 5C.

Referring to FIG. 5E, the first member 200 and the second member 1300 on which the electrophoretic layer 400 is formed are combined with each other.

Referring to FIG. 5F, the protective film 520 is formed on the second member 1300.

According to the present embodiment described with reference to FIGS. 5A, 5B, 5C, 5D, 5E and 5F, the second member 1300 is combined with the first member 200 after the electrophoretic layer 400 is formed on the second member 1300. Alternatively, the first member 200 may be combined with the second member 1300 after the electrophoretic layer 400 is formed on the first member 200.

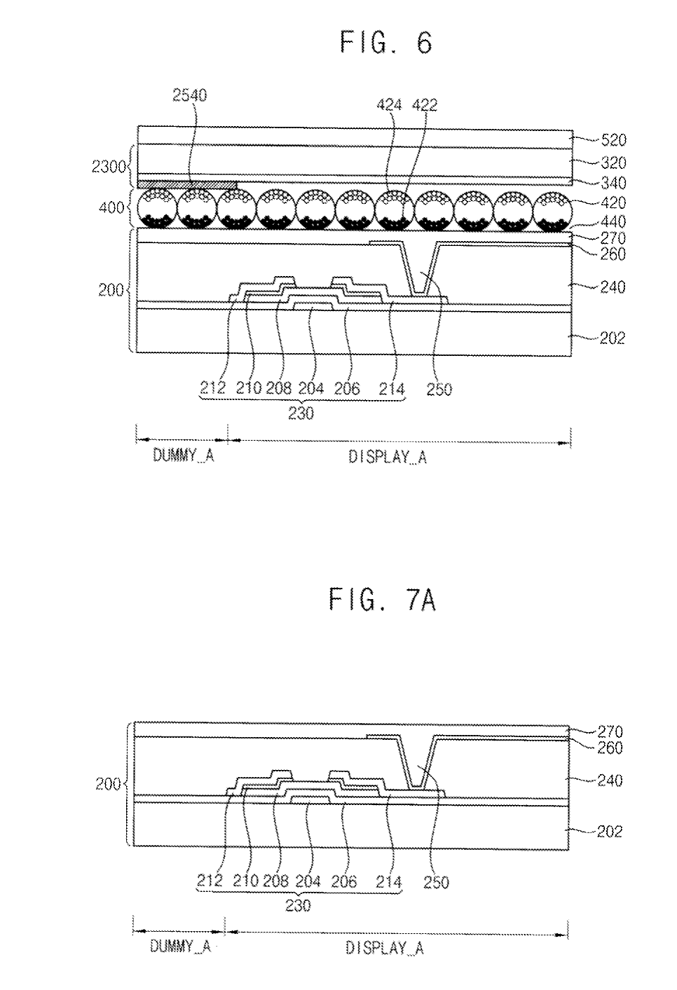

FIG. 6 is a cross-sectional view illustrating a dummy area and a portion of a display area of an electrophoretic display panel according to still another embodiment of the present invention.

The electrophoretic display panel according to the present embodiment is substantially the same as the electrophoretic display panel according to the previous embodiment in FIG. 2, with one of the differences being that an outer member 2540 is formed on the common electrode 340. Thus, the same reference numerals will be used to refer to the parts described above and any repetitive explanation concerning those elements will be omitted.

Referring to FIG. 6, the electrophoretic display panel according to the present embodiment includes the first member 200, the second member 2300, the electrophoretic layer 400 and the protective film 520.

The second member 2300 includes the second substrate 320, the common electrode 340 and the outer member 2540.

The outer member 2540 may be formed on the common electrode 340 and formed in the area covering the dummy area DUMMY_A disposed outside of the display area DISPLAY_A. For example, the outer member 2540 may be formed between the electrophoretic layer 400 and the common electrode 340.

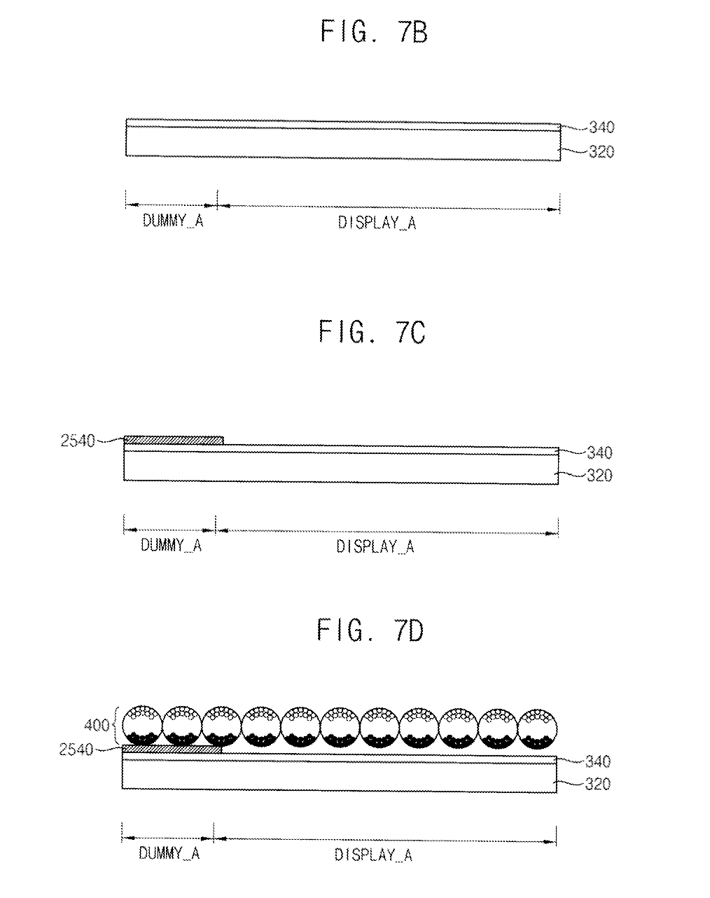

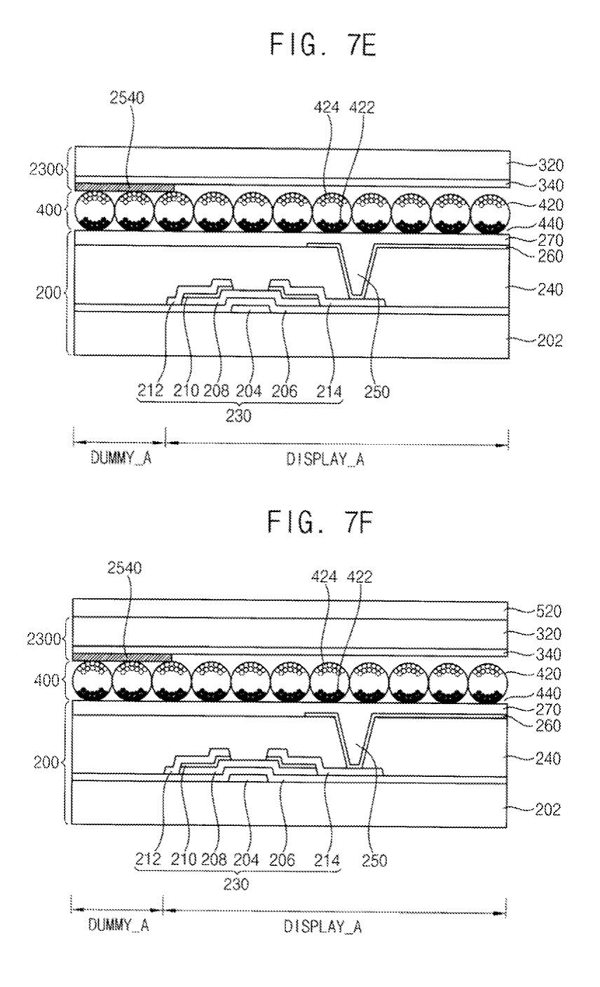

FIGS. 7A, 7B, 7C, 7D, 7E and 7F are cross-sectional views explaining a method of manufacturing the electrophoretic display panel of FIG. 6.

Referring to FIG. 7A, the first member 200 is formed. The first member 200 may be formed in substantially the same manner as the first member 200, as described above with reference to FIGS. 3A, 3B, 3C and 3D.

Referring to FIG. 7B, the common electrode 340 is formed on the second substrate 320 to overlap with the display area DISPLAY_A and the dummy area DUMMY_A.

Referring to FIG. 7C, the outer member 2540 is formed on the common electrode 340 to overlap with the dummy area DUMMY_A.

Referring to FIG. 7D, the electrophoretic layer 400 is formed on the second member 2300 manufactured as illustrated in FIGS. 7B and 7C.

Referring to FIG. 7E, the first member 200 and the second member 2300 on which the outer member 2540 and the electrophoretic layer 400 are formed are combined with each other.

Referring to FIG. 7F, the protective film 520 is formed on the second member 2300.

According the present embodiment described with reference to FIGS. 7A, 7B, 7C, 7D, 7E and 7F, the second member 2300 is combined with the first member 200 after the electrophoretic layer 400 is formed on the second member 2300. Alternatively, the first member 200 may be combined with the second member 2300 after the electrophoretic layer 400 is formed on the first member 200.

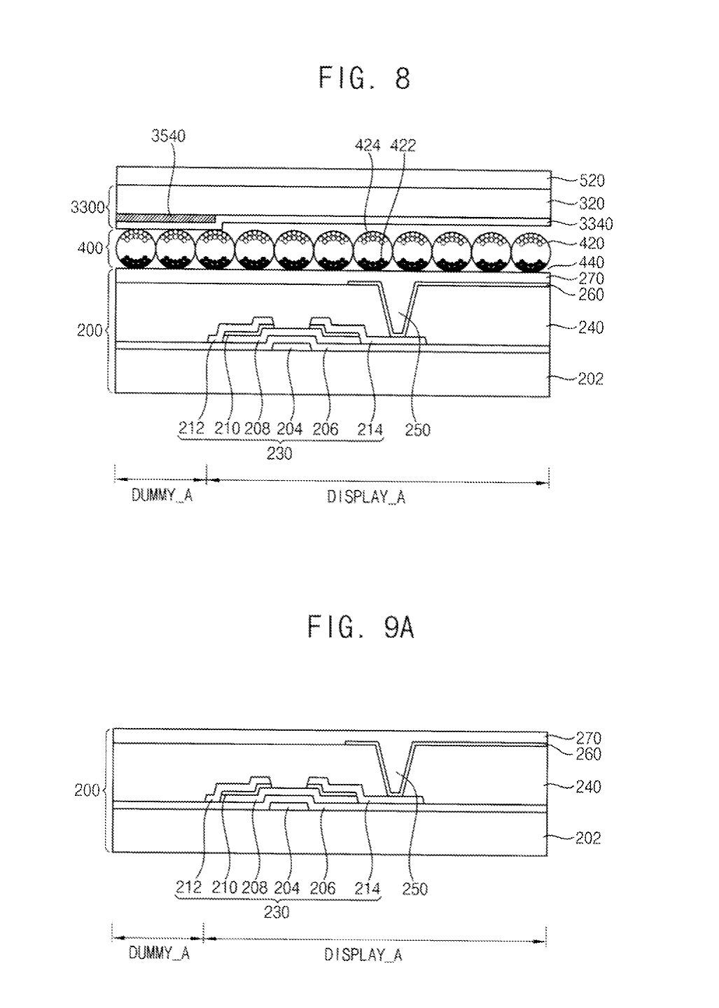

FIG. 8 is a cross-sectional view illustrating a dummy area and a portion of a display area of an electrophoretic display panel according to still another embodiment of the present invention.

The electrophoretic display panel according to the present embodiment is substantially the same as the electrophoretic display panel according to the previous embodiment in FIG. 2, with one of the differences being the position of an outer member 3540. Thus, the same reference numerals will be used to refer to the parts described above and any repetitive explanation concerning those elements will be omitted.

Referring to FIG. 8, the electrophoretic display panel according to the present embodiment includes the first member 200, the second member 3300, the electrophoretic layer 400 and the protective film 520.

The second member 3300 includes the second substrate 320, a common electrode 3340 and the outer member 3540.

The outer member 3540 may be formed on the second substrate 320 and formed in the area covering the dummy area DUMMY_A disposed outside of the display area DISPLAY_A. The common electrode 3340 may be formed in the display area DISPLAY_A and also over the outer member 3540, resulting in formation of a step in the common electrode 3340. In this case, the outer member 3540 is formed between the second substrate 320 and the common electrode 3340.

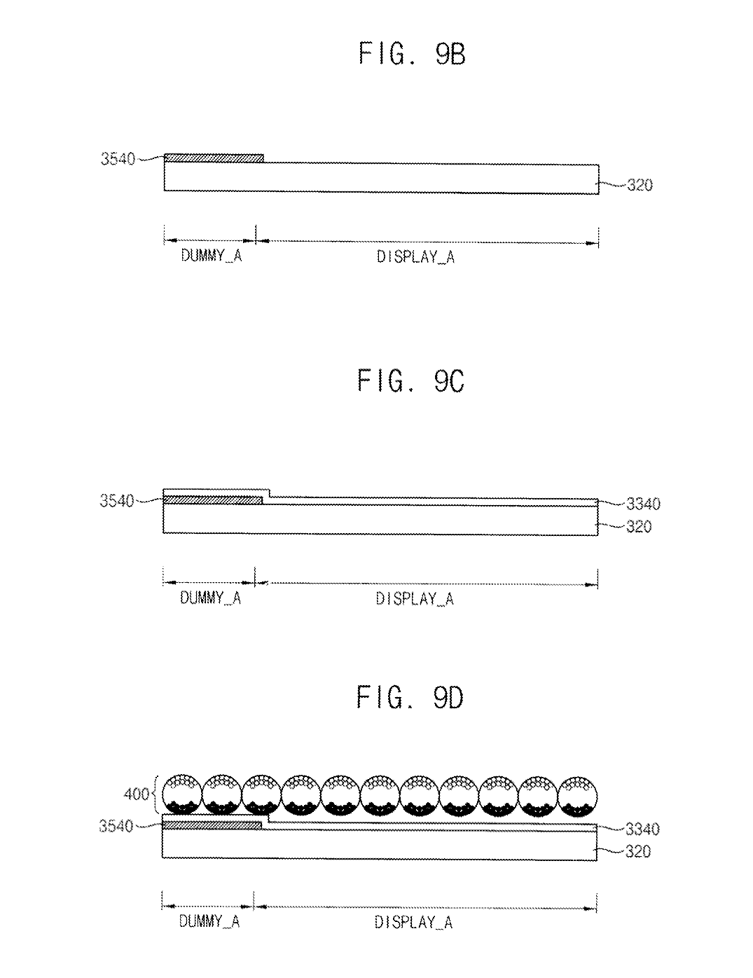

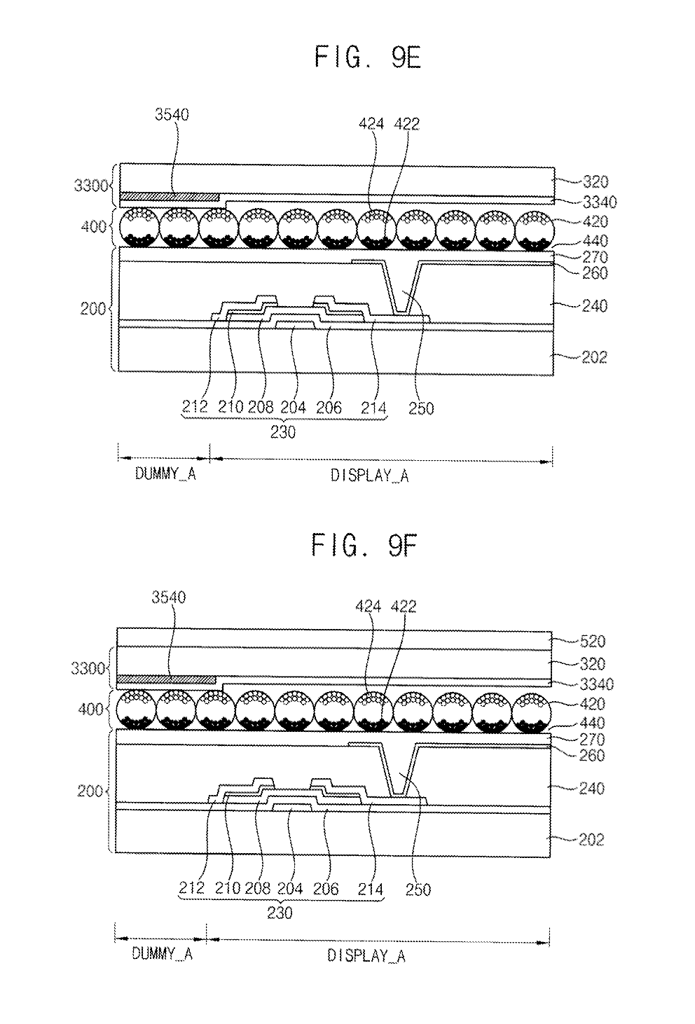

FIGS. 9A, 9B, 9C, 9D, 9E and 9F are cross-sectional views explaining a method of manufacturing the electrophoretic display panel of FIG. 8.

Referring to FIG. 9A, the first member 200 is formed. Forming of the first member 200 may be done substantially in the manner described above with reference to FIGS. 3A, 3B, 3C and 3D.

Referring to FIG. 9B, the outer member 3540 is formed on the second substrate 320 to overlap with the dummy area DUMMY_A.

Referring to FIG. 9C, the common electrode 3340 is formed between the outer member 3540 and the second substrate 320. In FIG. 9C, the common electrode 3340 forms a stepped portion due to the outer member 3540 formed on the second substrate 320. In some embodiments, the common electrode 3340 is formed to have a constant thickness regardless of whether it is in the dummy area DUMMY_A or the display area DISPLAY_A. In this case, the height of the step would be substantially equal to the thickness of the outer member 3540. In other embodiments, the common electrode 3340 may be made thicker in the display area DISPLAY_A than in the dummy area DUMMY_A to planarize an upper surface of the common electrode 3340.

Referring to FIG. 9D, the electrophoretic layer 400 is formed on the second member 3300 manufactured as illustrated in FIGS. 9B and 9C.

Referring to FIG. 9E, the first member 200 and the second member 3300 on which the electrophoretic layer 400 and the outer member 3540 are formed are combined with each other.

Referring to FIG. 9F, the protective film 520 is formed on the second member 3300.

According to the present embodiment described with reference to FIGS. 9A, 9B, 9C, 9D, 9E and 9F, the second member 3300 is combined with the first member 200 after the electrophoretic layer 400 is formed on the second member 3300. Alternatively, the first member 200 may be combined with the second member 3300 after the electrophoretic layer 400 is formed on the first member 200.

FIG. 10 is a cross-sectional view illustrating a dummy area and a portion of a display area of an electrophoretic display panel according to still another embodiment of the present invention.

The electrophoretic display panel according to the present embodiment is substantially the same as the electrophoretic display panel according to the embodiment in FIG. 2 with one of the differences being that an outer member 4540 is formed on a protective film 4520. Thus, the same reference numerals will be used to refer to the parts described above and any repetitive explanation concerning those elements will be omitted.

Referring to FIG. 10, the electrophoretic display panel according to the present embodiment includes the first member 200, the second member 300, the electrophoretic layer 400, the protective film 4520 and the outer member 4540.

The protective film 4520 is formed on the second member 300 and formed in an area covering the display area DISPLAY_A and the dummy area DUMMY_A.

The outer member 4540 is formed on the protective film 4520 and formed in the area covering the dummy area DUMMY_A.

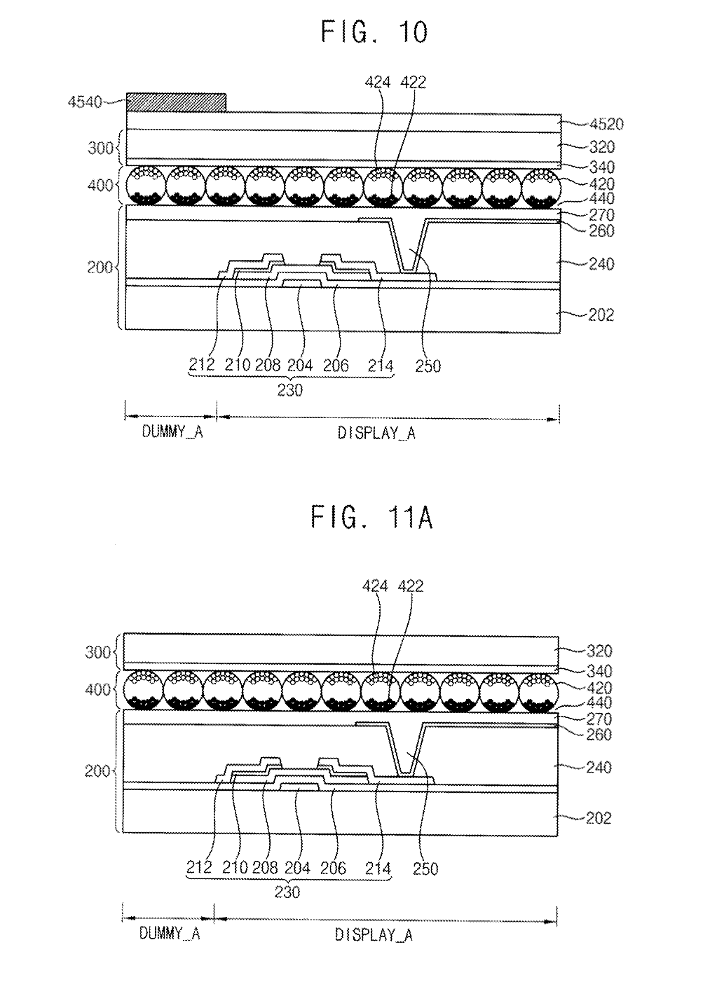

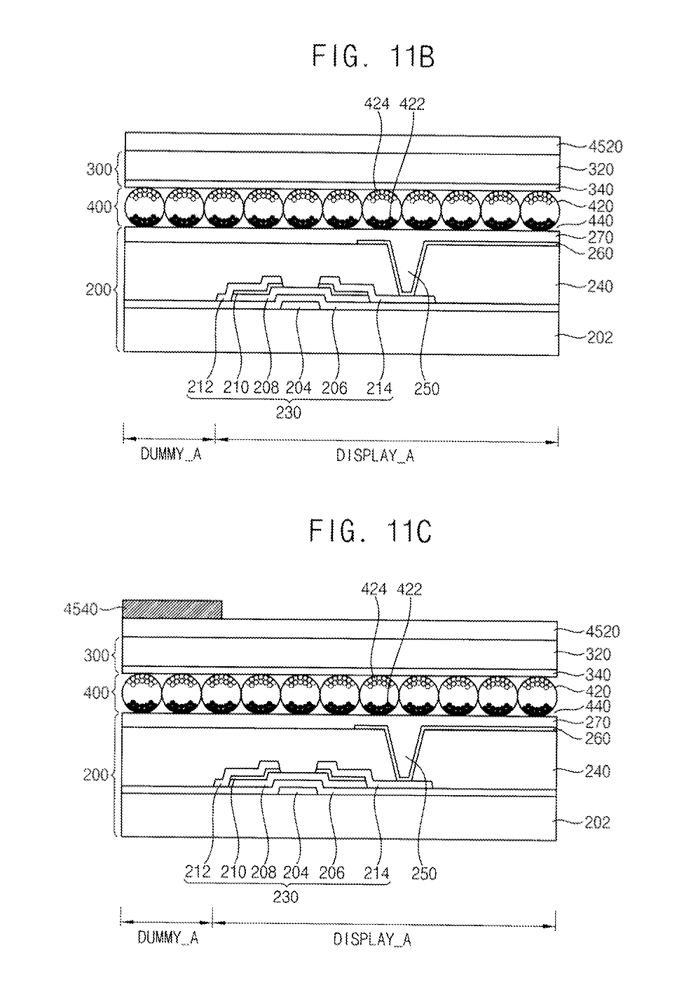

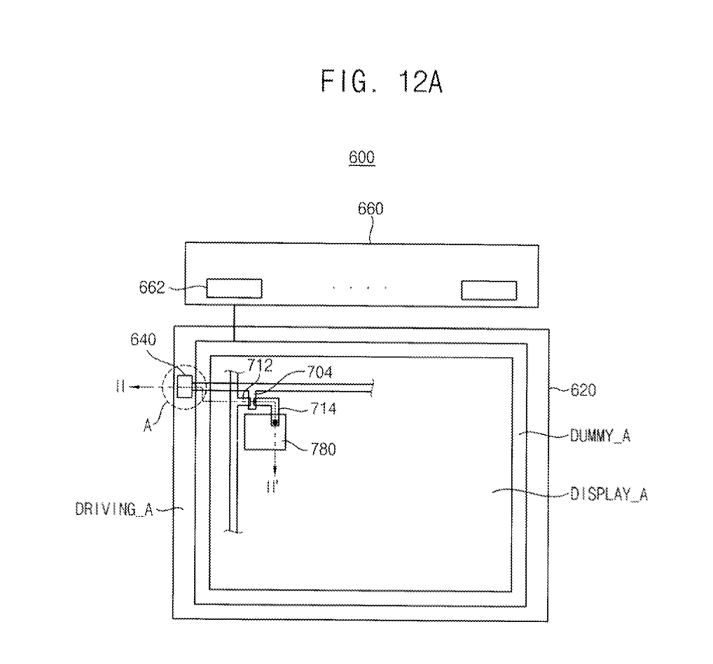

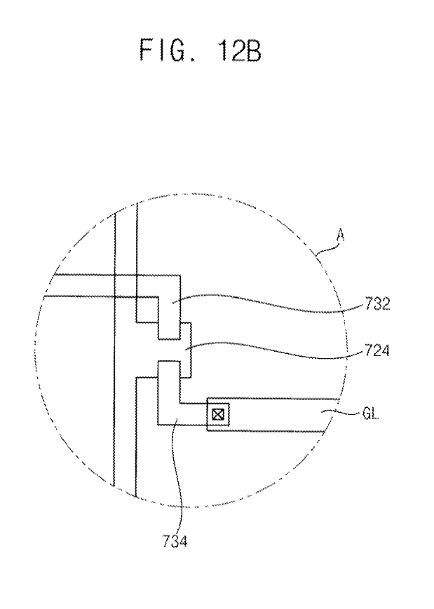

FIGS. 11A, 11B and 11C are cross-sectional views explaining a method of manufacturing the electrophoretic display panel of FIG. 10.

Referring to FIG. 11A, the first member 200, the electrophoretic layer 400 and the second member 300 are formed. Forming the first member 200, the electrophoretic layer 400 and the second member 300 may follow substantially the same order as forming the first member 200, the electrophoretic layer 400 and the second member described with reference to FIGS. 3A, 3B, 3C, 3D, 3E, 3F and 3G.

Referring to FIG. 11B, the protective film 4520 is formed on the second member 300 to overlap with the display area DISPLAY_A and the dummy area DUMMY_A.

Referring to FIG. 11C, the outer member 4540 is formed on the protective film 4520 to overlap with the dummy area DUMMY_A.

Therefore, the electrophoretic display panels of FIGS. 4, 6, 8 and 10 includes the outer members 1540, 2540, 3540 and 4540 covering the dummy area DUMMY_A disposed outside of the display area DISPLAY_A to prevent random color from being displayed in the dummy area DUMMY_A. By preventing the formation of visual artifact in the dummy area DUMMY_A, the outer member 1540, 2540, 3540, 4540 enhance image quality.

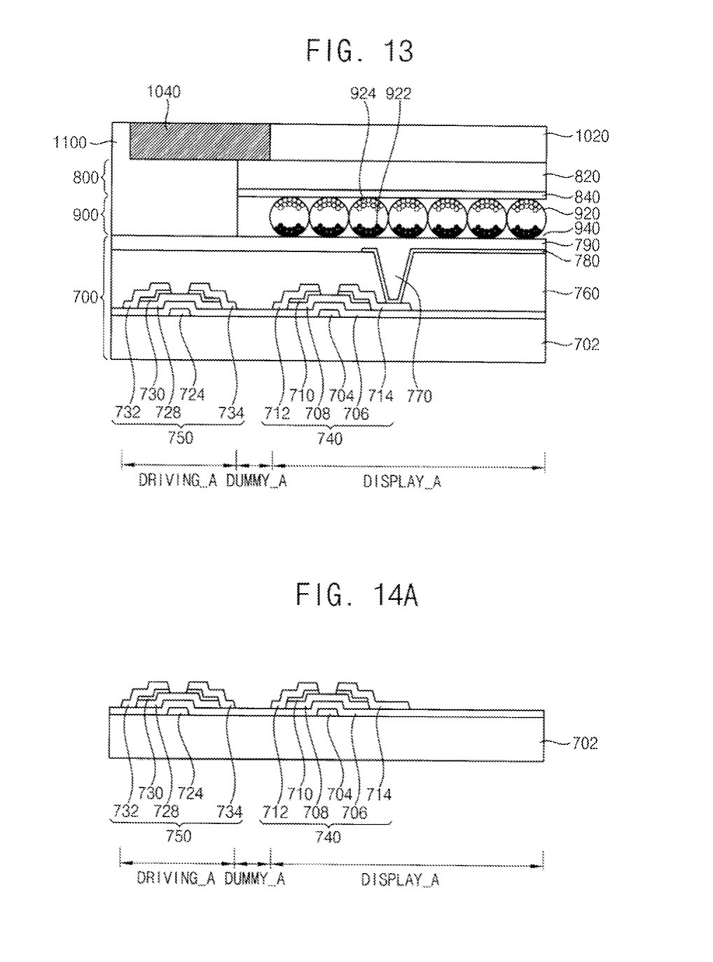

FIG. 12A is a conceptual diagram illustrating an electrophoretic display apparatus according to still another embodiment of the present invention. FIG. 12B is an enlarged view illustrating a portion ‘A’ of FIG. 12A. FIG. 13 is a cross-sectional view taken along a line II-II′ in FIG. 12A to illustrate a driving area, a dummy area and a portion of a display area of an electrophoretic display panel in FIG. 12A.

Referring to FIGS. 12A, 12B and 13, the electrophoretic display apparatus 600 according to the present embodiment includes an electrophoretic display panel 620, a gate driving part 640 and a data driving part 660.

The electrophoretic display panel 620 includes a display area DISPLAY_A in which a gate line GL and a data line DL intersecting with the gate line GL are formed, a dummy area DUMMY_A formed outside of the display area DISPLAY_A, and a driving area DRIVINGA formed adjacent to the dummy area DUMMY_A.

The display area DISPLAY_A includes a first TFT 740 connected to the gate line GL and the data line DL.

The gate driving part 640 is disposed in the driving area DRIVING_A and includes an amorphous silicon gate (ASG). For example, the driving area DRIVING_A may include a second TFT 750 applying a gate signal to the gate line GL.

The second TFT 750 may be substantially the same as the first TFT 740 and may be manufactured using a process substantially the same as the process for manufacturing the first TFT 740.

The data driving part 660 includes a plurality of data driving chips 662. The data driving chip 662 applies a data signal to the data line DL of the electrophoretic display panel 620.

The electrophoretic display panel 620 includes a first member 700, a second member 800 and an electrophoretic layer 900.

The first member 700 includes a first substrate 702 having the display area DISPLAY_A, the dummy area DUMMY_A and the driving area DRIVING_A, the first and second TFTs 740 and 750 formed on the first substrate 702, a protection film 760 formed on the first and second TFTs 740 and 750, and a pixel electrode 780 formed on the protection film 760 and electrically connected to a drain electrode 714 of the first TFT 740 through a contact hole 770 formed through the protection film 760.

The first TFT 740 includes a first gate electrode 704 formed on the first substrate 702 and extending from the gate line GL, a gate insulation layer 706 formed on the first gate electrode 704, a first active layer 708 formed on the gate insulation layer 706, a first ohmic-contact layer 710 formed on the first active layer 708, a first source electrode 712 formed on the first ohmic-contact layer 710 and extending from the data line DL, and the first drain electrode 714 formed on the first ohmic-contact layer 710 and spaced apart from the first source electrode 712.

The second TFT 750 includes a second gate electrode 724 formed on the first substrate 702, the gate insulation layer 706 formed on the second gate electrode 724, a second active layer 728 formed on the gate insulation layer 706, a second ohmic-contact layer 730 formed on the second active layer 728, a second source electrode 732 formed on the second ohmic-contact layer 730, and the second drain electrode 734 formed on the second ohmic-contact layer 730 and spaced apart from the second source electrode 732.

The first member 700 may further include an adhesive layer 790 on the protection film 760 and the pixel electrode 780, so that the protection film 760 and the pixel electrode 780 may attach to the electrophoretic layer 900 disposed on the first member 700.

The second member 800 includes a second substrate 820 facing the first substrate 702 of the first member 700 and a common electrode 840 formed on a first surface of the second substrate 820.

The second member 800 may be formed in an area overlapping with the display area DISPLAY_A and the dummy area DUMMY_A.

The electrophoretic layer 900 is formed between the first member 700 and the second member 800. The electrophoretic layer 900 displays an image using an electric field generated between the pixel electrode 780 of the first member 700 and the common electrode 840 of the second member 800.

The electrophoretic layer 900 includes a microcapsule 920 and a binder 940 protecting and fixing the microcapsule 920. The microcapsule 920 includes a black particle 922 charged with a negative (−) charge and a white particle 924 charged with a positive (+) charge.

Therefore, the black particle 922 responds to a positive voltage and the white particle 924 responds to a negative voltage. The black particle 922 may include a carbon material, and the white particle 924 may include a titanium dioxide (TiO2) material.

The protective film 1020 and the outer member 1040 are formed on the second member 800.

For example, the protective film 1020 is formed in an area covering the display area DISPLAY_A, and formed on a second surface facing the first surface on which the common electrode 840 is formed. The outer member 1040 is formed in an area covering the dummy area DUMMY_A and the driving area DRIVING_A, and formed on the second surface.

The protective film 1020 may transmit light. The protective film 1020 may prevent moisture and ultraviolet ray from permeating into the electrophoretic layer 900 from outside of the electrophoretic display panel 620.

The outer member 1040 may contact the protective film 1020 formed in the area overlapping with the display area DISPLAY_A to overlap with the dummy area DUMMY_A and the driving area DRIVING_A.

The outer member 1040 may be achromatic. For example, the outer member 1040 may be black.

A width of the outer member 1040 may be uniform outside of the display area DISPLAY_A.

The outer member 1040 may include a material that blocks light. For example, the outer member 1040 may include an organic material. Thus, the outer member 1040 may block light reflected by the electrophoretic layer 900.

Therefore, the electrophoretic display apparatus 600 includes the outer member 1040 covering the dummy area DUMMY_A disposed outside of the display area DISPLAY_A to prevent random color from being displayed in the dummy area DUMMY_A. This way, image quality may be enhanced.

Additionally, the outer member 1040 is formed over the second TFT 750 in an area overlapping with the second TFT 750, and thus the outer member 1040 may block the light that would have other been incident on the second TFT 750. Therefore, the electrophoretic display apparatus 600 may prevent leakage current and damage of the second TFT 750.

The electrophoretic display apparatus 600 may further include a sealant 1100 formed between the first member 700 and the outer member 1040 in the area overlapping with the dummy area DUMMY_A, and a side area of the outer member 1040 facing the protective film 1020.

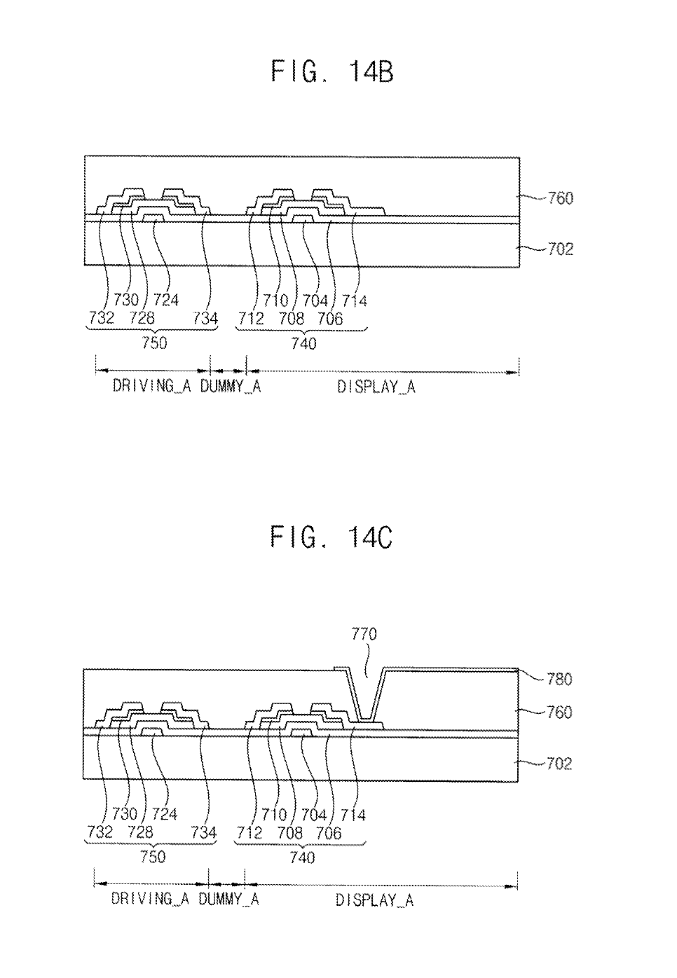

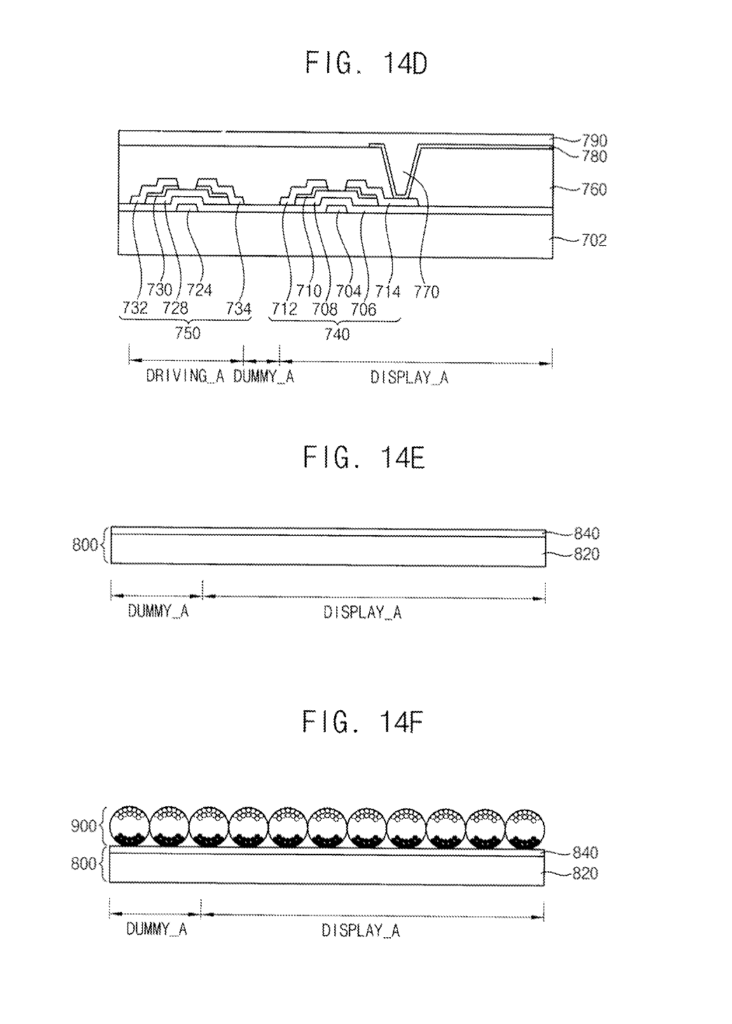

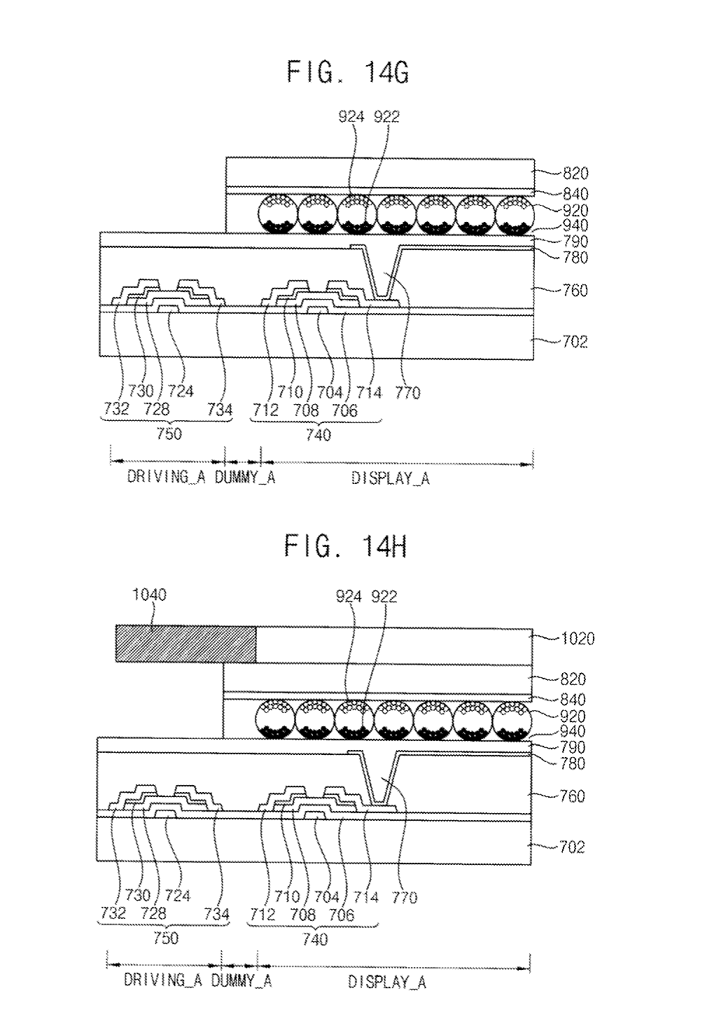

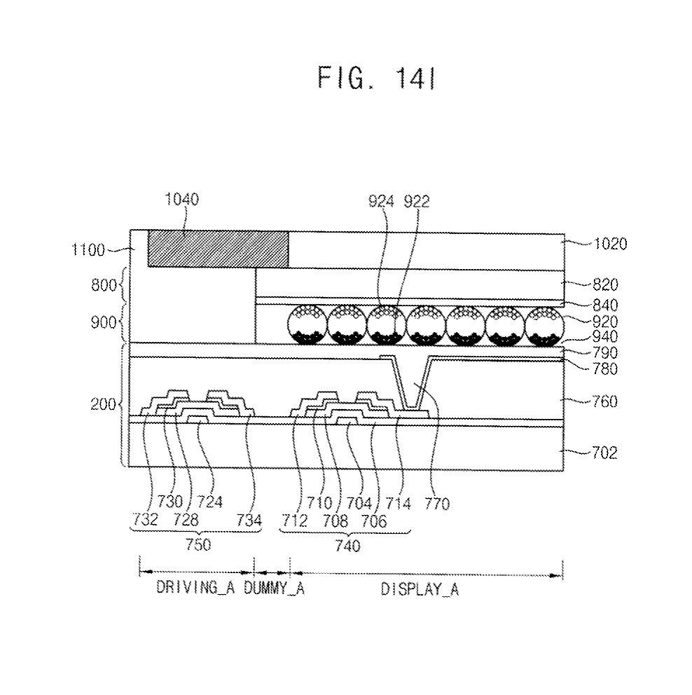

FIGS. 14A, 14B, 14C, 14D, 14E, 14F, 14G, 14H and 14I are cross-sectional views explaining a method of manufacturing the electrophoretic display panel of FIG. 13.

Referring to FIG. 14A, the first TFT 740 is formed on the first substrate 702 in the display area DISPLAY_A, and the second TFT 750 is formed on the first substrate 702 in the driving area DRIVING_A spaced apart from the display area DISPLAY_A.

For example, the first gate electrode 704 and the second gate electrode 724 are formed on the first substrate 702. The gate insulation layer 706 is formed on the first and second gate electrodes 704 and 724. The first active layer 708 and the second active layer 728 are formed on the gate insulation layer 706. The first ohmic contact layer 710 is formed on the first active layer 708 and the second ohmic contact layer 730 is formed on the second active layer 728. The first source electrode 712 extended from the data line DL and the first drain electrode 714 spaced apart from the first source electrode 712 are formed on the first ohmic contact layer 710. The second source electrode 732 and the second drain electrode 734 spaced apart from the second source electrode 732 are formed on the second ohmic contact layer 730.

Referring to FIG. 14B, the protection film 760 is formed on the first substrate 702 on which the first and second TFTs 740 and 750 are formed.

The protection film 760 is formed to cover the first and second TFTs 740 and 750. The protection film 760 may include an organic material such as acrylic, polyimide, benzocyclobutene and so on.

Referring to FIG. 14C, the pixel electrode 780 is partially formed on the protection film 760.

The pixel electrode 780 is electrically connected to the first drain electrode 714 of the first TFT 740 through a contact hole 770 formed through the protection film 760. The pixel electrode 780 may include ITO or IZO.

Referring to FIG. 14D, the adhesive layer 790 is formed on the pixel electrode 780 and the protection film 760. The adhesive layer 790 may include at least one of polyester resin, acrylic resin, epoxy resin and urethane resin.

Referring to FIG. 14E, the common electrode 840 is formed on the second substrate 820 to form the second member 800.

Referring to FIG. 14F, the electrophoretic layer 900 is formed on the common electrode 840 of the second member 800.

The electrophoretic layer 900 may overlap with the display area DISPLAY_A and the dummy area DUMMY_A.

The electrophoretic layer 900 includes the microcapsule 920 and the binder 940 protecting and fixing the microcapsule 920. The microcapsule 920 includes the black particle 922 charged with the negative (−) charge and the white particle 924 charged with the positive (+) charge.

Referring to FIG. 14G, the first member 700 and the second member 800 on which the electrophoretic layer 900 is formed are combined with each other.

Referring to FIG. 14H, the protective film 1020 and the outer member 1040 are formed on the second member 800.

For example, the protective film 1020 is formed in the area overlapping with the display area DISPLAY_A, and the outer member 1040 is formed in the area overlapping with the dummy area DUMMY_A and the driving area DRIVING_A.

The protective film 1020 and the outer member 1040 may be formed on the second member 800, after the protective film 1020 formed in the area overlapping with the display area DISPLAY_A and the outer member 1040 formed in the area overlapping with the dummy area DUMMY_A are combined with each other.

In addition, the outer member 1040 may contact the protective film 1020 and may be formed in the area overlapping with the dummy area DUMMY_A and the driving area DRIVING_A, after the protective film 1020 is formed in the area overlapping with the display area DISPLAY_A.

Referring to FIG. 14I, the sealant 1100 is formed between the first member 700 and the outer member 1040 in the area overlapping with the dummy area DUMMY_A and the driving area DRIVING_A, and the side area of the outer member 1040 facing the protective film 1020.

According to the present embodiment described with reference to FIGS. 14A, 14B, 14C, 14D, 14E, 14F, 14G, 14H and 14I, the second member 800 is combined with the first member 700 after the electrophoretic layer 900 is formed on the second member 800. Alternatively, the first member 700 may be combined with the second member 800 after the electrophoretic layer 900 is formed on the first member 700.

According to the electrophoretic display panel, the method of manufacturing the electrophoretic display panel and the electrophoretic display apparatus having the electrophoretic display panel of the present invention, an achromatic (e.g., black) outer member that blocks light is formed outside of the display area, and thus the black color is displayed in the outside of the display area in a uniform width.

Additionally, according to the electrophoretic display panel, the method of manufacturing the electrophoretic display panel and the electrophoretic display apparatus having the electrophoretic display panel of the present invention, the outer member is formed in the area overlapping with the ASG, and thus the leakage current and the damage of the amorphous silicon gate may be prevented. Thus, display quality of the electrophoretic display apparatus may be enhanced.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims.

What is claimed is:

1. An electrophoretic display panel comprising:
a first member including a first substrate and a pixel electrode formed on the first substrate, the first substrate having a display area and a dummy area disposed outside of the display area;
a second member including a second substrate facing the first substrate and a common electrode formed on a first surface of the second substrate;
an electrophoretic layer disposed between the first member and the second member and displaying an image by an electric field generated between the pixel electrode and the common electrode; and
an outer member covering the dummy area and blocking light.

2. The electrophoretic display panel of claim 1, further comprising:
a protective film formed on the second substrate and covering the display area,
wherein the outer member and the protective film are formed on substantially the same plane.

3. The electrophoretic display panel of claim 1, wherein the outer member is formed on the first surface of the second substrate, and the common electrode covers the outer member.

4. The electrophoretic display panel of claim 1, wherein the outer member is formed on the common electrode.

5. The electrophoretic display panel of claim 1, wherein the outer member is achromatic.

6. The electrophoretic display panel of claim 5, wherein the outer member is black.

7. The electrophoretic display panel of claim 1, further comprising:
a protective film formed on a second surface of the second substrate and covering the display area,
wherein the outer member is formed on the protective film and covers the dummy area.

8. The electrophoretic display panel of claim 1, wherein the first substrate further includes at least one thin-film transistor (TFT) formed in a driving area adjacent to the dummy area and applying a gate signal to a gate line of the display area.

9. The electrophoretic display panel of claim 8, wherein the outer member overlaps with the driving area in which the TFT is formed.

10. The electrophoretic display panel of claim 1, wherein a width of the outer member corresponding to upper and lower side portions of the dummy area is uniform.

11. The electrophoretic display panel of claim 1, wherein a width of the outer member corresponding to left and right side portions of the dummy area is uniform.

12. The electrophoretic display panel of claim 1, wherein a width of the outer member corresponding to upper, lower, left and right side portions of the dummy area is uniform.

13. A method of manufacturing an electrophoretic display panel, the method comprising:
forming a first member including a first substrate and a pixel electrode formed on the first substrate, the first substrate having a display area and a dummy area disposed outside of the display area;
forming a second member including a second substrate facing the first substrate and a common electrode formed on a first surface of the second substrate;
forming an electrophoretic layer on one of the first and second members;
combining the first member and the second member to position the electrophoretic layer between the first and the second members; and
forming an outer member on the second member, the outer member covering the dummy area and blocking light.

14. The method of claim 13, wherein the outer member is formed via a coating process.

15. The method of claim 13, wherein the outer member is formed via a film lamination process.

16. The method of claim 13, wherein the first member further comprises a driving area adjacent to the dummy area, and the outer member is formed in an area overlapping with the driving area.

17. An electrophoretic display apparatus comprising:
a first member including a first substrate and a pixel electrode formed on the first substrate, the first substrate having a display area and a dummy area disposed outside of the display area;
a second member including a second substrate facing the first substrate and a common electrode formed on a first surface of the second substrate;
an electrophoretic layer disposed between the first member and the second member and displaying an image by an electric field generated between the pixel electrode and the common electrode;
an outer member covering the dummy area and blocking light;
a gate driving part applying a gate signal to a gate line of the display area; and
a data driving part applying a data signal to a data line of the display area.

18. The electrophoretic display apparatus of claim 17, wherein the gate driving part is disposed in a driving area adjacent to the dummy area, and includes at least one TFT applying the gate signal to the gate line of the display area.

19. The electrophoretic display apparatus of claim 18, wherein the outer member overlaps with the driving area.
